(19) United States
(12) Patent Application Publication
(10) Pub. No.: US 2014/0251541 A1
(43) Pub. Date: Sep. 11, 2014

(54) PLASMA PROCESSING APPARATUS

(71) Applicant: TOKYO ELECTRON LIMITED, Tokyo (JP)

(72) Inventors: Toshihiko IWAO, Sendai City (JP); Toshihisa NOZAWA, Sendai City (JP)

(73) Assignee: TOKYO ELECTRON LIMITED, Tokyo (JP)

(21) Appl. No.: 14/200,386

(22) Filed: Mar. 7, 2014

(30) Foreign Application Priority Data
Mar. 8, 2013 (JP) 2013-046950

(51) Int. Cl. H01J 37/32

(52) U.S. Cl. CPC H01J 37/32293
USPC 156/345.41; 118/723 MW

(57) ABSTRACT

Disclosed is a plasma processing apparatus including: a processing container having a cylindrical columnar shape centering around a predetermined axis and defining a processing space therein; a plurality of columnar dielectric bodies installed at a top side of the processing space; a microwave generator configured to generate microwaves; a waveguide unit configured to connect the microwave generator and the plurality of columnar dielectric bodies; and a stage installed within the processing container to intersect with the predetermined axis. The plurality of columnar dielectric bodies are arranged at predetermined intervals along a circumferential direction around the predetermined axis within the processing space. The waveguide unit branches microwaves input from the microwave generator and supplies the branched microwaves to the plurality of columnar dielectric bodies.

### CROSS-REFERENCE TO RELATED APPLICATIONS

This application is based on and claims priority from Japanese Patent Application No. 2013-046950 filed on Mar. 8, 2013 with the Japan Patent Office, the disclosure of which is incorporated herein in its entirety by reference.

### TECHNICAL FIELD

The present disclosure relates to a plasma processing apparatus.

### BACKGROUND

In a semiconductor device manufacturing process, a processing gas is excited to perform etching or film forming on a substrate to be processed. Plasma may be generated using various methods such as a capacity coupling method and an induction coupling. However, as for a plasma source, microwaves capable of generating plasma of a low electron temperature and a high density have attracted attention. International Publication No. WO2011/125524 discloses a plasma processing apparatus that employs such microwaves as a plasma source.

The plasma processing apparatus disclosed in WO2011/125524 includes a processing container, a stage, a processing gas supply unit, an antenna, and a microwave generator. The processing container accommodates therein a stage on which a substrate to be processed is mounted. The antenna is installed above the stage. The antenna is referred to as a radial slot antenna and connected to a microwave generator via a coaxial waveguide. In addition, the antenna includes a cooling jacket, a dielectric plate, a slot plate, and a dielectric window. The dielectric plate has a substantially disc shape and is sandwiched between the cooling jacket made of a metal and the slot plate in a vertical direction. The slot plate is formed with a plurality of slot holes. The slot holes are arranged in a circumferential direction and radial direction about a central axis of the coaxial waveguide. The dielectric window of the substantially disc shape is installed just below the slot plate. The dielectric window closes a top opening of the processing container. In addition, the supplying gas supply unit includes a center gas supply unit and an outer gas supply unit. The center gas supply unit supplies a processing gas from the center of the dielectric window. The outer gas supply unit is provided in an annular shape between the dielectric window and the stage and supplies a processing gas in an area lower than the center gas supply unit.

### SUMMARY

A plasma processing apparatus according to an aspect of the present disclosure includes: a processing container having a cylindrical columnar shape centering around a predetermined axis and defining a processing space therein; a plurality of columnar dielectric bodies installed at a top side of the processing space; a microwave generator configured to generate microwaves; a waveguide unit configured to connect the microwave generator and the plurality of columnar dielectric bodies; and a stage installed within the processing container to intersect with the predetermined axis. The plurality of columnar dielectric bodies are arranged at predetermined intervals along a circumferential direction around the predetermined axis within the processing space, and the waveguide unit branches microwaves input from the microwave generator and supplies the branched microwaves to the plurality of columnar dielectric bodies.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a cross-sectional view schematically illustrating a plasma processing apparatus according to a first exemplary embodiment.

FIG. 2 is a cross-sectional view schematically illustrating a microwave supply unit of the plasma processing apparatus according to the first exemplary embodiment.

FIGS. 3A and 3B are a perspective view and a horizontal cross-sectional view illustrating a branching device, respectively.

FIG. 4 is a cross-sectional view schematically illustrating a plasma processing apparatus according to a second exemplary embodiment.

FIG. 5 is a cross-sectional view schematically illustrating a microwave supply unit of the plasma processing apparatus according to the second exemplary embodiment.

FIG. 6 is a cross-sectional view schematically illustrating a microwave supply unit according to a third exemplary embodiment.

FIG. 7 is a horizontal cross-sectional view illustrating a branching adjustment mechanism.

FIG. 8 is a cross-sectional view schematically illustrating a microwave supply unit according to a fourth exemplary embodiment.

FIG. 9 is a cross-sectional view schematically illustrating a configuration of a microwave supply unit according to a fifth exemplary embodiment.

FIG. 10 is a perspective view illustrating a configuration of a plasma processing apparatus used in a text example.

FIG. 11 is a views representing images of light emission states of plasma.

### DETAILED DESCRIPTION

In the following detailed description, reference is made to the accompanying drawing, which form a part hereof. The illustrative exemplary embodiments described in the detailed description, drawing, and claims are not meant to be limiting. Other exemplary embodiments may be utilized, and other changes may be made without departing from the spirit or scope of the subject matter presented here.

In a plasma processing apparatus, it is requested to reduce a variation in processing on the entire surface of a substrate to be processed. For this purpose, it is required to optimize a density distribution of plasma within the processing container.

In the plasma processing apparatus disclosed in WO2011/125524, a phenomenon so-called “mode jump” that a plasma generation position is changed may occur when generating plasma by microwaves. The mode jump occurs since an electric field strength distribution is varied when a surface wave propagated along a load surface of an antenna is varied according to a process condition such as, for example, a pressure, a gas flow rate, or a input microwave power. In addition, in the plasma processing apparatus, plasma tends to be generated unevenly in density such that the plasma density at the center of the substrate to be processed is high and the plasma density at the edge of the substrate to be processed is low. Thus, in the apparatus disclosed in WO2011/125524, it may be difficult to control a plasma generation position and to control a proper plasma density on a surface of a wafer.

Accordingly, what is requested in the related technical field is to improve controllability of a plasma generation position in a plasma processing apparatus that excites plasma within a processing container by supplying microwaves from an antenna.

A plasma processing apparatus according to an aspect of the present disclosure includes: a processing container having a cylindrical columnar shape centering around a predetermined axis and defining a processing space therein; a plurality of columnar dielectric bodies installed at a top side of the processing space; a microwave generator configured to generate microwaves; a waveguide unit configured to connect the microwave generator and the plurality of columnar dielectric bodies; and a stage installed within the processing container to intersect with the predetermined axis. The plurality of columnar dielectric bodies are arranged at predetermined intervals along a circumferential direction around the predetermined axis within the processing space, and the waveguide unit branches microwaves input from the microwave generator and supplies the branched microwaves to the plurality of columnar dielectric bodies.

In the plasma processing apparatus, microwaves input from a waveguide path are propagated to the plurality of columnar dielectric bodies disposed in the processing space. Accordingly, plasma generation positions are concentrated in the vicinity of the plurality of columnar dielectric bodies. Thus, the plasma processing apparatus is excellent in controllability of plasma generating positions. In addition, the plurality of columnar dielectric bodies are arranged at predetermined intervals along the circumferential direction around the predetermined axis of the processing container. Accordingly, the plasma processing apparatus may generate plasma at distributed positions in the circumferential direction around the predetermined axis. Further, since the plasma generated as described above is diffused toward the stage, a plasma density distribution may be formed of which the variation in the circumferential direction and radial direction is reduced on the stage. In addition, since the microwaves input from the microwave generator are branched and supplied to the plurality of columnar dielectric bodies, the energy of microwaves supplied to each of the columnar dielectric bodies may be reduced. As a result, because most of the energy of the microwaves may be consumed in each of the columnar dielectric bodies, occurrence of reflected waves at the reflection end of each of the columnar dielectric bodies may be suppressed. Thus, the processing apparatus may suppress occurrence of standing waves of which the field strength distribution is uneven, and as a result, the variation of plasma generation positions may be suppressed.

In an exemplary embodiment, the processing container includes a top wall that defines the processing space from the top side. The top wall is formed with a plurality of openings in the circumferential direction around the predetermined axis, and the plurality of columnar dielectric bodies extend in a direction parallel to the predetermined axis through the plurality of openings.

In the present exemplary embodiment, because the plurality of columnar dielectric bodies extend from the lateral side of the processing container to the inside through the openings, plasma may be generated at distributed positions in the circumferential direction around the axis.

In an exemplary embodiment, the processing container includes a top wall that defines the processing space from the top side. The top wall is formed with a plurality of openings in the circumferential direction around the predetermined axis, and the plurality of columnar dielectric bodies extend in a direction parallel to the predetermined axis through the plurality of openings.

According to the present exemplary embodiment, since the plurality of columnar dielectric bodies extend in the direction parallel to the predetermined axis through the openings formed along the circumferential direction around the predetermined axis, plasma may be generated at distributed positions in the circumferential direction around the predetermined axis.

In an exemplary embodiment, the waveguide unit may include a branching adjustment mechanism configured to adjust a branching ratio of the microwaves. According to the present exemplary embodiment, the energy of microwaves supplied to each of the plurality of columnar dielectric bodies may be adjusted.

In an exemplary embodiment, the columnar dielectric body may be made of quartz or ceramics such as alumina. The specific dielectric coefficient of quartz is 3.8 to 4.2 and the specific dielectric coefficient of alumina is 9 to 10. When the columnar dielectric bodies are made of quartz, each of the columnar dielectric bodies may be formed in a cylindrical columnar shape having a diameter of 35 mm to 45 mm. In addition, when the columnar dielectric bodies are made of alumina, each of the columnar dielectric bodies may be formed in a cylindrical columnar shape having a diameter of 23 mm to 30 mm. Within a dielectric body covered by a metal, microwaves are propagated in a TE11 mode as a basic mode. Meanwhile, within a dielectric body surrounded by plasma, microwaves are propagated in a HE11 mode as a basic mode. In the case where the columnar dielectric bodies are made of quartz, when the diameter of each of the columnar dielectric bodies is set to 35 mm or more, and in the case where the columnar dielectric bodies are made of alumina, when the diameter of each of the columnar dielectric bodies is set to 23 mm or more, microwaves may be propagated in the columnar dielectric bodies surrounded by the top wall or the side wall, i.e. by a metal, in the TE 11 mode. In addition, in the case where the columnar dielectric bodies are made of quartz, when the diameter of each of the columnar dielectric bodies is set to 45 mm or less, and in addition, in the case where the columnar dielectric bodies are made of alumna, when the diameter of each of the columnar dielectric bodies is set to 30 mm or less, occurrence of a high-order mode may be prevented when microwaves are propagated in the HE11 mode within the columnar dielectric bodies in the processing space where the plasma is generated.

As described above, according to various aspects and exemplary embodiments of the present disclosure, a plasma processing apparatus may be provided in which controllability of plasma generation positions is improved in a plasma processing apparatus that excites plasma within the processing container by supplying microwaves from an antenna.

Hereinafter, various exemplary embodiments will be described in detail with reference to accompanying drawings. In the drawings, like elements will be denoted like reference numerals.

### First Exemplary Embodiment

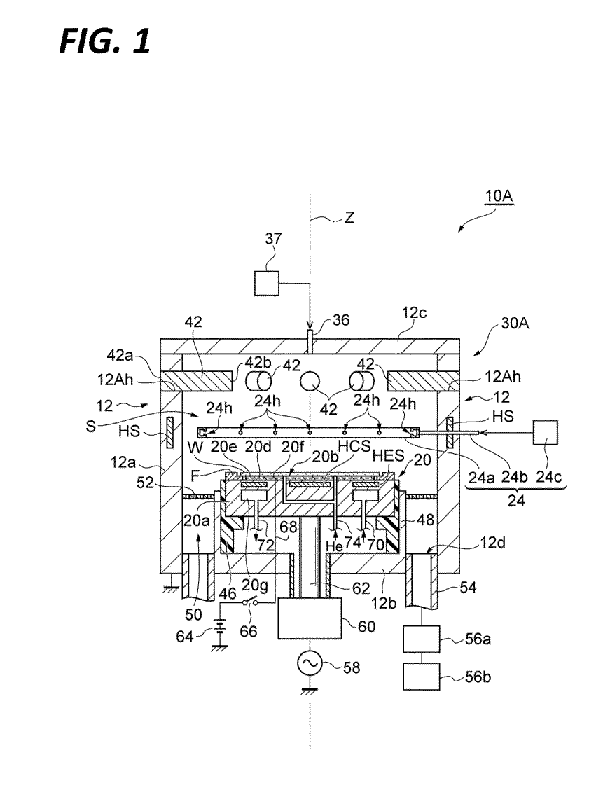

FIG. 1 is a cross-sectional view schematically illustrating a plasma processing apparatus according to a first exemplary embodiment. For the convenience of description, a microwave generator 28 and a waveguide unit 38 which will be described later are omitted in FIG. 1. The plasma processing apparatus 10A illustrated in FIG. 1 is provided with a processing container 12. The processing container 12 defines a processing space S in which a substrate to be processed W is accommodated. The processing container 12 may include a side wall 12a, a bottom wall 12b, and a top wall 12c. The side wall 12a has a substantially cylindrical columnar shape extending in a direction where a predetermined axis Z extends (hereinafter, referred to as a “Z-axis direction”). The bottom wall 12b is provided at the bottom end side of the side wall 12a. The bottom wall 12b is provided with an exhaust hole 12d for exhausting a gas. The top wall 12c has a disc shape with the Z-axis as a center and is provided at the top end of the side wall 12a.

The plasma processing apparatus 10A further includes a stage 20 provided within the processing container 12. The stage 20 is installed within the processing space S to intersect with the Z-axis below the top wall 12c. On the stage 20, a substrate to be processed W may be mounted such that the center of the substrate to be processed W substantially coincides with the Z-axis. In an exemplary embodiment, the stage 20 includes a table 20a, and an electrostatic chuck 20b.

The table 20a is supported on a cylindrical supporting unit 46. The cylindrical supporting unit 46 is made of an insulating material and extends vertically upwardly from the bottom wall 12b. In addition, a conductive cylindrical supporting unit 48 is provided at the outer periphery of the cylindrical supporting unit 46. The cylindrical supporting unit 48 extends vertically upwardly from the bottom wall 12b of the processing container 12 along the outer periphery of the cylindrical supporting unit 46. An annular exhaust path 50 is formed between the cylindrical supporting unit 48 and the side wall 12a.

An annular baffle plate 52 provided with a plurality of through holes are attached above the exhaust path 50. The exhaust path 50 is connected to exhaust tubes 54 that provide exhaust holes 12d, and an exhaust apparatus 56b is connected to the exhaust tubes 54 via a pressure regulator 56a. The exhaust apparatus 56b includes a vacuum pump such as a turbo molecular pump. The pressure regulator 56a adjusts the exhaust amount of the exhaust apparatus 56b so as to adjust the pressure within the processing container 12. The processing space S within the processing container 12 may be decompressed to a desired degree of vacuum by the pressure regulator 56a and the exhaust apparatus 56b. In addition, when the exhaust apparatus 56b is operated, the processing gas may be exhausted from the outer periphery of the stage 20 through the exhaust path 50.

The table 20a also serves as a high-frequency electrode. To the table 20a, a high-frequency power source 58 for RF bias is electrically connected via a matching assembly 60 and a power feeding rod 62. The high-frequency power source 58 outputs a high-frequency power having a frequency suitable for controlling the energy of ions to be attracted to the substrate to be processed W, for example, 13.65 MHz, as a predetermined power. The matching assembly 60 accommodates a matching unit configured to match the impedance of the high-frequency power source 58 and the impedance of the load side which mainly includes an electrode, plasma, and the processing container 12. A blocking condenser configured to generate self-bias is incorporated in the matching unit.

An electrostatic chuck 20b is installed on the top surface of the table 20a. In an exemplary embodiment, the top surface of the electrostatic chuck 20b forms a mounting region where the substrate to be processed W is mounted. The electrostatic chuck 20b holds the substrate to be processed W with an electrostatic attractive force. A focus ring F is provided radially outside the electrostatic chuck 20b to annularly surround the perimeter of the substrate to be processed W. The electrostatic chuck 20b includes an electrode 20d, an insulation film 20e, and an insulation film 20f. The electrode 20d is made of a conductive film and provided between the insulation film 20e and the insulation film 20f. To the electrode 20d, a high voltage direct current (DC) power source 64 is electrically connected via a switch 66 and a coated wire 68. The electrostatic chuck 20b is capable of attracting and holding the substrate to be processed W on the top surface thereof using a coulomb force generated by the direct current voltage applied from the direct current power source 64.

Within the table 20a, an annular coolant chamber 20g is provided which extends in the circumferential direction. In the coolant chamber 20g, a coolant of a predetermined temperature, for example, cooling water, is supplied in circulation from a chiller unit via pipes 70, 72. The processing temperature of the substrate to be processed W on the electrostatic chuck 20b may be controlled according to the temperature of the coolant. In addition, a heat transfer gas from a heat transfer gas supply unit, for example, He gas, is supplied to a gap between the top surface of the electrostatic chuck 20b and the rear surface of the substrate to be processed W through a gas supply tube 74.

In an exemplary embodiment, the plasma processing apparatus 10A may further include heaters HS, HCS, HES as a temperature control mechanism. The heater HS is installed inside the side wall 12a and extends annularly. The heater HS may be installed, for example, at a position corresponding to a middle portion of the processing space S in the height direction (i.e., in the direction of the Z-axis). The heater HCS is installed within the table 20a. The heater HCS is installed the below the central position of the above-mentioned mounting region within the table 20a, i.e. at a region intersecting with the Z-axis. In addition, the HES is installed within the table 20a and extends annularly to surround the heater HCS. The heater HES is installed below the outer peripheral edge portion of the above-mentioned mounting region.

In an exemplary embodiment, in the top wall 12c, a conduit 36 extends through the top wall 12c along the Z-axis. The conduit 36 is connected to a gas supply unit 37. The gas supply unit 37 is a gas source that controls the flow rate of a processing gas for processing the substrate to be processed W and supplies the processing gas to the conduit 36. The gas supply unit 37 may include, for example, an open/close valve and a mass flow controller.

The gas supply unit 37 introduces the processing gas into the processing space S through the conduit 36 and along the Z-axis. The processing gas is properly selected according to a processing performed on the substrate to be processed W within the plasma processing apparatus 10A. For example, when performing etching on the substrate to be processed W, the processing gas may include, for example, an etchant gas and/or an inert gas, or when performing film-forming on the substrate to be processed W, the processing gas may include, for example, a raw material gas and/or an inert gas.

In addition, the plasma processing apparatus 10A further includes a gas supply unit 24. The gas supply unit 24 includes an annular tube 24a, a pipe 24b, and a gas source 24c. The annular tube 24a is installed within the processing container 12 at a middle position of the processing space S in the direction of the Z-axis to extend in an annular shape about the Z-axis. The annular tube 24a is formed with a plurality of gas injection holes 24h opened toward the Z-axis. The plurality of gas injection holes 24h are arranged annularly around the Z-axis. The pipe 24b is connected to the annular tube 24a. The pipe 24b extends to the outside of the processing container 12 and is connected to the gas source 24c. The gas source 24c is a gas source of a processing gas, just like the gas supply unit 37 in which the gas source 24c controls the flow rate of the processing gas and supplies the processing gas to the pipe 24b. The gas source 24c may include, for example, an open/close valve and a mass flow controller.

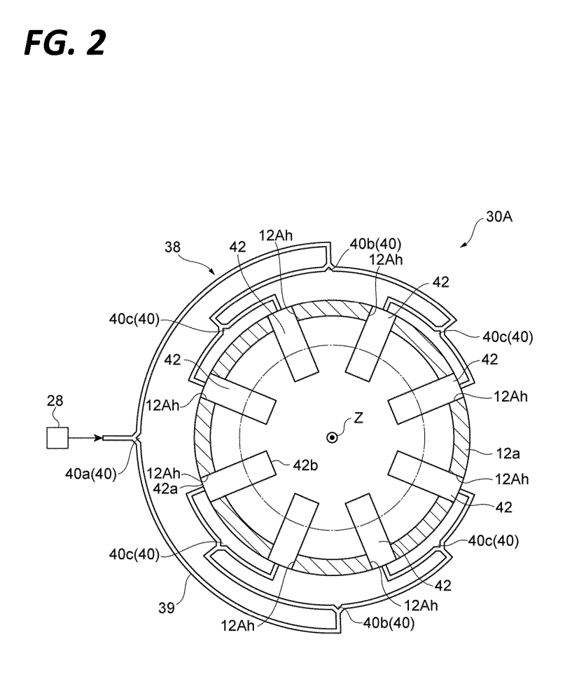

The plasma processing apparatus 10A further includes a microwave supply unit 30A. Hereinafter, descriptions will be made on the microwave supply unit 30A with reference to FIG. 2 together with FIG. 1. FIG. 2 is a cross-sectional view schematically illustrating a microwave supply unit 30A. The microwave supply unit 30A includes a microwave generator 28, a waveguide unit 38, and a plurality of columnar dielectric bodies 42. The microwave generator 28 generates microwaves of, for example, 2.45 GHz. The microwave generator 28 is connected to one end of the waveguide unit 38 to as to supply the generated microwaves to the waveguide unit 38.

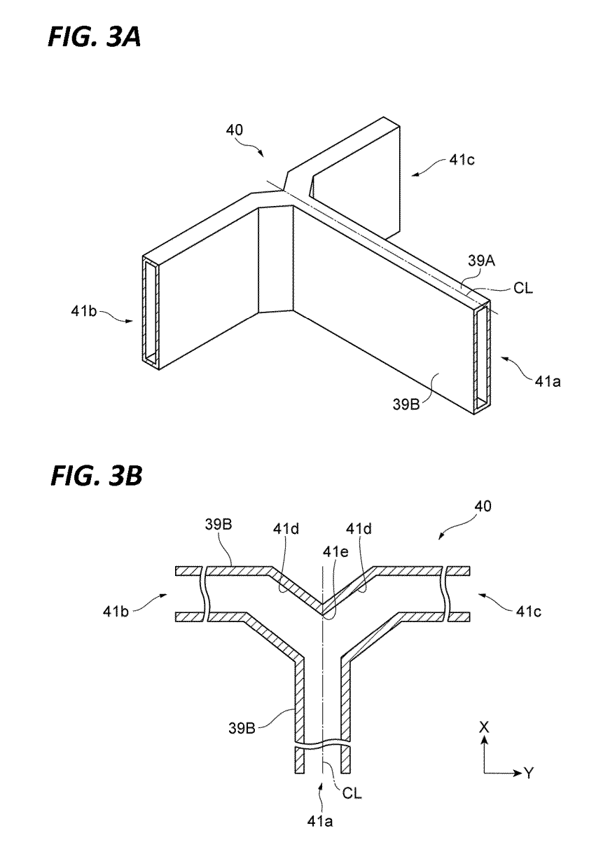

The waveguide unit 38 includes a waveguide 39. The waveguide 39 is a tubular member that propagates the microwaves to the inner space. The waveguide 39 is, for example, a flat rectangular waveguide having a pair of walls 39A which correspond to short sides in the cross section thereof and a pair of walls 39B which correspond to the long sides in the cross section (see, e.g., FIG. 3).

The waveguide unit 38 branches the microwaves input from the microwave generator 28 and supplies the branched microwaves to the plurality of columnar dielectric bodies 42. Specifically, the waveguide unit 38 branches the microwaves input from the microwave generator 28 in steps, and supplies the branched microwaves to the plurality of columnar dielectric bodies 42, respectively. For this reason, the waveguide unit 38 includes a plurality of branching devices 40 configured to branch the microwaves. FIG. 3A is a perspective view illustrating one branching device 40, and FIG. 3B is a horizontal cross-sectional view thereof. The branching device 40 has a substantially “Y” shape and includes a first port 41a, a second port 41b, and a third port 41c. The branching device 40 branches microwaves input from the first port 41a and evenly outputs the branched microwaves input from the second port 41b and the third port 41c. For the convenience of description, in FIG. 3B, the progressing direction of the microwaves input from the first port 41a is deemed as an X-axis direction and a direction orthogonal to the X-axis is deemed as a Y-axis direction.

The branching device 40 has walls 39B that face the first port 41a in which the walls 39B include a pair of inclined surfaces 41d inclined toward the first port 41a. As illustrated in FIG. 3B, a portion where the pair of inclined surfaces 41d intersect with each other, i.e. the top side 41e intersects with the central axis CL of the pair of walls 39A. Since the branching device 40 includes the pair of inclined surfaces 41d, occurrence of reflected waves may be suppressed when the microwaves are branched.

In the exemplary embodiment of FIG. 2, seven (7) branching devices 40 are installed on a propagation path of the microwaves of the waveguide unit 38. Hereinafter, a branching device 40 that branches the microwaves input from the microwave generator 28 first will be referred to as a “first branching device 40a”. In addition, a branching device 40 that branches the microwaves branched by the first branching device 40a will be referred to as a “second branching device 40b”, and a branching device 40 that branches the microwaves branched by the second branching device 40b will be referred to as a “third branching device 40c”. In the exemplary embodiment illustrated in FIG. 2, one (1) first branching device 40a, two (2) second branching devices 40b, and four (4) third branching devices 40c are provided.

The side wall 12a is formed with a plurality of openings 12Ah. The plurality of openings 12Ah are formed through the side wall in a direction orthogonal to the Z-axis. In addition, the plurality of openings 12Ah are provided between the annular tube 24a and the top wall 12c in the height direction. Such openings 12Ah are arranged in the circumferential direction with respect to the Z-axis at predetermined intervals. Each of the openings 12Ah has a diameter D.

The plurality of columnar dielectric bodies 42 extend to the processing space S through the plurality of openings 12Ah, respectively. Each of the columnar dielectric bodies 42 has a rod shape, i.e. a cylindrical columnar shape to pass through one of the plurality of openings 12Ah. Each of the columnar dielectric bodies 42 has a base end portion 42a and a tip end portion 42b. The positions of the base end portions 42a of the columnar dielectric bodies 42 coincide with the outer surface of the side wall 12a. In addition, the columnar dielectric bodies 42 are configured such that the tip end portions 42b thereof extend to the inside of the inner surface of the side wall 12a to be positioned within the processing space S. That is, the plurality of columnar dielectric bodies 42 are arranged to have predetermined intervals in the circumferential direction around the Z-axis within the processing space S and each of the columnar dielectric bodies 42 extends toward the center of the processing container 12 from the outer peripheral surface of the side wall 12a. In addition, the other end of the waveguide unit 38 is connected with the base end portions 42a of the columnar dielectric bodies 42. The plurality of columnar dielectric bodies 42 are made of a dielectric material, for example, quartz.

In an exemplary embodiment, each of the columnar dielectric bodies 42 has a cylindrical columnar shape of a diameter D and inserted into one of the opening 12Ah without a gap. The columnar dielectric bodies 42 may be made of quartz or ceramics such as alumina. Here, the specific dielectric constant of the quartz is 3.8 to 4.2 and the specific dielectric constant of the alumina is 9 to 10. When the columnar dielectric bodies 42 are made of quartz, each of the columnar dielectric bodies 42 may have a diameter of 35 mm to 45 mm. Alternatively, when the columnar dielectric bodies 42 are made of alumina, each of the columnar dielectric bodies 42 may have a diameter of 23 mm to 30 mm. At the portions of the columnar dielectric bodies 42 covered by the side wall 12a (i.e., the portions which are in contact with the metallic wall that defines the openings 12Ah), microwaves are propagated in a TE11 mode as a basic mode. When the diameter D of each of the columnar dielectric bodies 42 is set to 35 mm or more in the case where the columnar dielectric bodies 42 are made of quartz, or when the diameter D of each of the columnar dielectric bodies 42 is set to 23 mm or more in the case where the columnar dielectric bodies 42 are made of alumina, the microwaves propagated as the TE11 mode are not blocked and the microwaves propagated through the waveguide unit 38 may be introduced into the columnar dielectric bodies 42. Meanwhile, at the portions of the columnar dielectric bodies 42 covered by plasma (i.e., the portions positioned within the processing space S), microwaves are propagated in a HE11 mode as a basic mode. When the diameter D of each of the columnar dielectric bodies 42 is set to 45 mm or less in the case where the columnar dielectric bodies 42 are made of quartz, or when the diameter D of each of the columnar dielectric bodies 42 is set to 30 mm or less in the case where the columnar dielectric bodies 42 are made of alumina, it is possible to prevent a high-order mode from being generated in the columnar dielectric bodies 42.

The microwaves propagated in the columnar dielectric bodies 42 excite the processing gas so as to generate plasma within the processing space S. Here, each of the columnar dielectric bodies 42 may have a length L which is determined based on the microwave power supplied from the microwave generator 28. For example, each of the columnar dielectric bodies 42 may have a length L which allows the energy of supplied microwaves to be consumed in the columnar dielectric bodies 42. In an exemplary embodiment, the lengths L of the columnar dielectric bodies 42 may be 20 mm or more.

When the microwave supply unit 30A is configured as described above, the microwaves supplied from the microwave generator 28 are divided into eight (8) parts by the first branching device 40a, the second branching devices 40b, and the third branching devices 40c while being propagated through the waveguide 39. In addition, the divided microwaves are introduced into the columnar dielectric bodies 42 that pass through the plurality of openings 12Ah, and supplied to the processing space S. In this manner, in the plasma processing apparatus 10A, the microwaves supplied from the microwave generator 28 are concentrated to the columnar dielectric bodies 42. As a result, plasma generation positions of the processing gas are concentrated in the vicinity of the plurality of columnar dielectric bodies 42. Accordingly, the plasma processing apparatus 10A is excellent in controllability of plasma generation positions.

Further, the plurality of columnar dielectric bodies 42 are arranged at predetermined intervals along the circumferential direction around the Z-axis within the processing space S and each of the columnar dielectric bodies 42 extends toward the center of the processing container 12 from the outer peripheral surface of the side wall 12a. Accordingly, in the plasma processing apparatus 10A, the plasma generation positions may be distributed in the circumferential direction of the Z-axis. In addition, the plasma generated as described above is diffused toward the stage 20. Thus, according to the plasma processing apparatus 10A, the variation in density distribution of plasma in the circumferential direction and the diametric direction (i.e., radial direction with respect to the Z-axis) on the stage may be reduced.

In addition, since each of the plurality of columnar dielectric bodies 42 has the length L, the tip end portions 42b of the columnar dielectric bodies 42 become the reflection ends, thereby suppressing occurrence of reflected waves. Thus, it is possible to suppress occurrence of standing waves which may occur within the columnar dielectric bodies 42 when reflected waves occur. As a result, the variation of plasma generation positions may be suppressed.

### Second Exemplary Embodiment

A plasma processing apparatus 10B according to the second exemplary embodiment is substantially equal to the plasma processing apparatus 10A according to the first exemplary embodiment, except that a microwave supply unit 30B is provided instead of the microwave supply unit 30A. The microwave supply unit 30B is different from the microwave supply unit 30A in the arrangements of the openings and columnar dielectric bodies. Hereinafter, in consideration of easy understanding of the description, the second exemplary embodiment will be described focusing on the features different from those of the first exemplary embodiment and overlapping descriptions will be omitted.

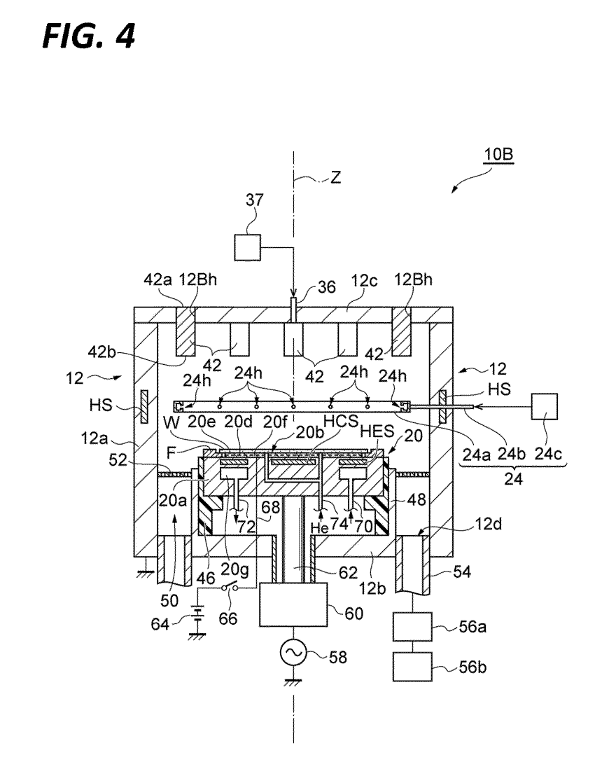

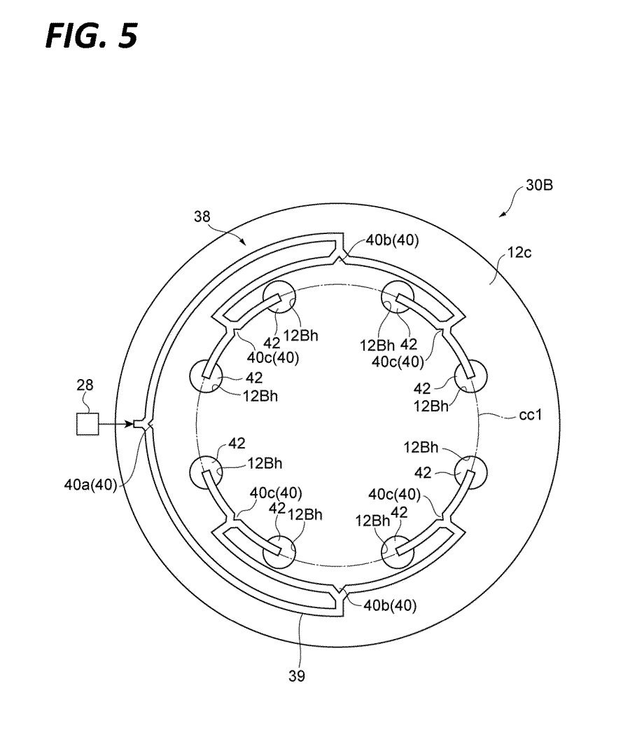

FIG. 4 is a cross-sectional view schematically illustrating plasma processing apparatus 10B according to the second exemplary embodiment. In addition, FIG. 5 is a cross-sectional view schematically illustrating the microwave supply unit of the plasma processing apparatus according to the second exemplary embodiment. Hereinafter, descriptions will be made on the plasma processing apparatus 10B with reference to FIGS. 4 and 5. As illustrated in FIGS. 4 and 5, in the plasma processing apparatus 10B, the openings 12Ah are not formed in the side wall 12a. Instead, a plurality of openings 12Bh are formed through the top wall 12c in the Z-direction.

The plurality of openings 12Bh are formed at predetermined intervals along a first circle cc1 centering around the Z-axis. In the exemplary embodiment, the plurality of openings 12Bh are arranged at predetermined intervals along the first circle cc1. In the exemplary embodiment, each of the openings 12Bh has a diameter D.

In addition, the plurality of columnar dielectric bodies 42 extend to the processing space S through the plurality of openings 12Bh. Each of the columnar dielectric bodies 42 has a rod shape, i.e. a cylindrical columnar shape to pass through one of the plurality of openings 12Bh. The top ends, i.e. the base end portions 42a of the columnar dielectric bodies 42 coincide with the height of the top surface of the top wall 12c. In addition, the columnar dielectric bodies 42 extend in the direction of the Z-axis downwardly below the bottom surface of the top wall 12c. The other end of the guide unit 38 is connected to the base end portions 42a of the plurality of columnar dielectric bodies 42 and supplied with microwaves from the microwave generator 28. The plasma processing apparatus 10B configured as described above is different from the plasma processing apparatus 10A in the arrangement of the plurality of columnar dielectric bodies 42. However, the plasma processing apparatus 10B is excellent in controllability of plasma generation positions and may reduce the variation in plasma density distribution in the circumferential direction and in the radial direction on the stage, just like the plasma processing apparatus 10A.

### Third Exemplary Embodiment

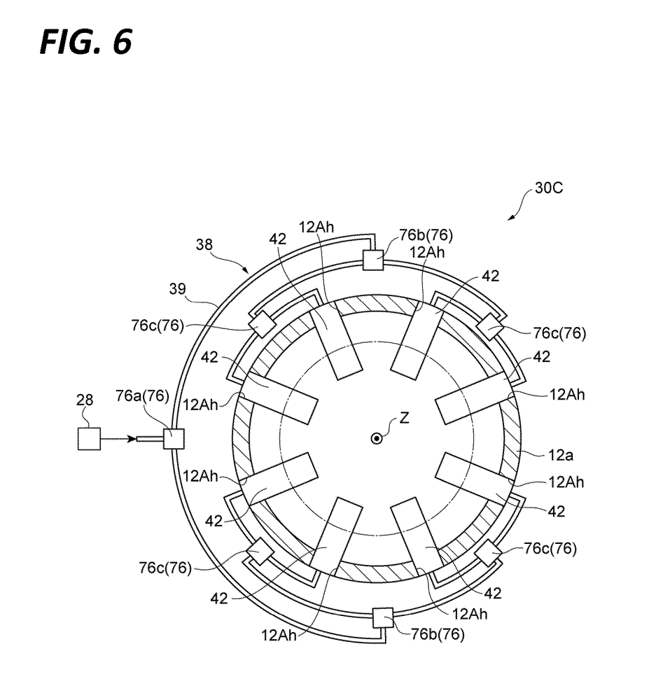

FIG. 6 is a cross-sectional view illustrating a microwave supply unit of a third exemplary embodiment. The exemplary embodiment relates to a microwave supply unit 30C that replaces the microwave supply unit 30A of the plasma processing apparatus 10A. As illustrated in FIG. 6, the microwave supply unit 30C is different from the microwave supply unit 30A in that branching adjustment mechanisms 76 are provided instead of the branching devices 40. The branching adjustment mechanisms 76 serve to adjust branching ratios of microwaves.

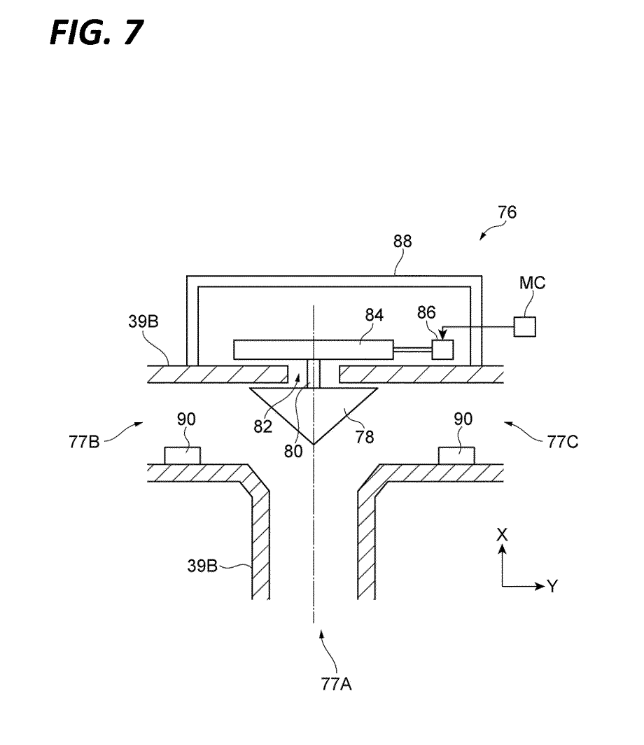

FIG. 7 is a horizontal cross-sectional view illustrating a schematic configuration of one branching adjustment mechanism 76. The branching adjustment mechanism 76 has a substantially “T” shape and includes a first port 77A, a second port 77B, and a third port 77C. The branching adjustment mechanism 76 branches the microwaves input from the first port 77A and evenly outputs the branched microwaves input from the second port 77B and the third port 77C. For the convenience of description, in FIG. 7, the progressing direction of the microwaves input from the first port 77A is deemed as an X-axis direction and a direction orthogonal to the X-axis is deemed as a Y-axis direction.

The branching adjustment mechanism 76 includes a branching unit 78, a joint 80, a guide 84, a motor 86 and a power monitor 90. The branching unit 78 provides a pair of inclined surfaces inclined toward the first port 77A. The branching unit 78 serves as a branching device that branches the microwaves input from the first port 77A. The branching adjustment mechanism 76 is connected with one end of the joint 80. The joint 80 extends to the outside of a wall 39B through a slit 82 formed in the wall 39B and along the X-axis direction. The other end of the joint 80 is connected with the guide 84. The guide 84 is connected with the motor 86 and configured to be movable in the Y-axis direction by a driving force from the motor 86. At the outside of the wall 39B, a shielding unit 88 is provided to cover the slit 82, the guide 84, and the motor 86. The shielding unit 88 prevents the microwaves that have passed through the slit 82 from leaking out to the outside. In addition, the motor 86 is electrically connected with the motor controller MC installed outside the shielding unit 88.

The power monitor 90 is installed in the vicinity of each of the second port 77B and the third port 77C of the branching adjustment mechanism 76. The power monitors 90 measure powers of microwaves branched by the branching unit 78 and output to the second port 77B and the third port 77C, respectively. The powers of microwaves measured by the power monitors 90 are output to the motor controller MC. The motor controller MC outputs a control signal that controls the driving of the motor 86 based on the outputs from the power monitors 90.

In the branching adjustment mechanism 76 configured as described above, the motor 86 generates a driving force based on the control signal from the motor controller MC and moves the guide 84 in the Y-axis direction. Thus, the branching unit 78 joined to the guide 84 through the joint 80 is moved in the Y-axis direction. When the branching unit 78 is moved in the Y-axis direction, a branching ratio of the microwaves input from the first port 77A in relation to the second port 77B and the third port 77C may be adjusted.

As described above, the plasma processing apparatus 10C according to the present exemplary embodiment may adjust the energy of microwaves supplied to each of the plurality of columnar dielectric bodies 42 since the waveguide 39 is provided with the plurality of branching adjustment mechanisms 76.

In addition, the branching adjustment mechanisms 76 of the present exemplary embodiment may be used instead of the branching devices 40 of the plasma processing apparatus 10B.

### Fourth Exemplary Embodiment

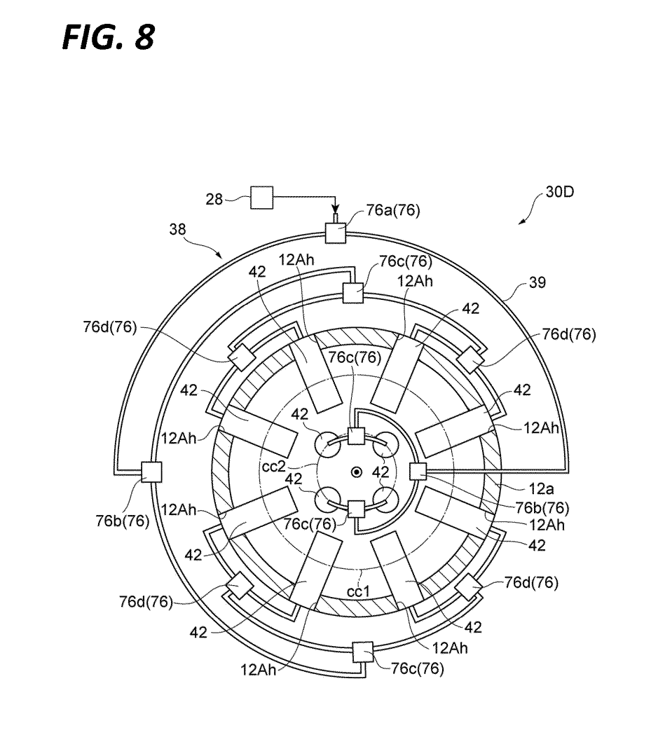

FIG. 8 is a cross-sectional view schematically illustrating a microwave supply unit 30D according to a fourth exemplary embodiment. The present exemplary embodiment is a modified aspect of the microwave supply unit 30C of the third exemplary embodiment and relates to a microwave supply unit 30D that replaces the microwave supply unit 30A of the plasma processing apparatus 10A. As illustrated in FIG. 8, in the microwave supply unit 30D, some of a plurality of columnar dielectric bodies 42 (in FIG. 8, eight (8) columnar dielectric bodies 42 positioned outside) are arranged at predetermined intervals along a first circle cc1 centering around the Z-axis within a processing space S and each of the columnar dielectric bodies 42 extends from the outer peripheral surface of a side wall 12a toward the center of a processing container 12. In addition, the others of the plurality of columnar dielectric bodies 42 (in FIG. 8, four (4) columnar dielectric bodies 42 positioned inside) are arranged at predetermined intervals along a second circle cc2 of which the diameter is smaller than that of the first circle cc1 centering around the Z-axis, and extend in the direction of the Z-axis. The columnar dielectric bodies 42 provided along the second circle cc2 extend to the processing space S through the top wall 12c. That is, the positions of the top ends of the columnar dielectric bodies 42 provided along the second circle cc2 coincide with the height of the top surface of the top wall 12c. In addition, the columnar dielectric bodies 42 provided along the second circle cc2 extend below the bottom surface of the top wall 12c in the direction of the Z-axis.

In FIG. 8, eleven (11) branching adjustment mechanisms 76 are connected on the path of the waveguide 39. In FIG. 8, a branching adjustment mechanism 76 that branches the microwaves input from the microwave generator 28 is referred to as a “first branching adjustment mechanism 76a”. In addition, a branching adjustment mechanism 76 that branches the microwaves branched by the first branching adjustment mechanism 76a is referred to as a “second branching adjustment mechanism 76b” and a branching adjustment mechanism 76 that branches the microwaves branched by the second branching adjustment mechanism 76b is referred to as a “third branching adjustment mechanism 76c”. In addition, a branching adjustment mechanism 76 that branches microwaves branched by the third branching adjustment mechanism 76c is referred to as a “fourth branching adjustment mechanism 76d”. The microwave supply unit 30D illustrated in FIG. 8 is provided with one (1) first branching adjustment mechanism 76a, two (2) second branching adjustment mechanisms 76b, four (4) third branching adjustment mechanisms 76c, and four (4) fourth branching adjustment mechanisms 76d. According to the microwave supply unit 30D, microwaves divided into sixteen (16) portions by the first branching adjustment mechanism 76a, the second branching adjustment mechanisms 76b, the third branching adjustment mechanisms 76c, and the fourth branching adjustment mechanisms 76d are supplied to the plurality of columnar dielectric bodies 42 arranged along the first circle cc1. In addition, microwaves divided into eight (8) portions by the first branching adjustment mechanism 76a, the second branching adjustment mechanisms 76b, and the third branching adjustment mechanisms 76c are supplied to the plurality of columnar dielectric bodies 42 arranged along the second circle cc2.

According to the microwave supply unit 30D, since the plurality of columnar dielectric bodies 42 are arranged along the second circle cc2 of which the diameter is smaller than that of the first circle cc1, it is possible to increase the plasma density in the vicinity of the Z-axis may be increased.

In addition, when the branching ratio of microwaves input from the microwave generator 28 is adjusted using the first branching adjustment mechanism 76a, the energy of microwaves supplied to the plurality of columnar dielectric bodies 42 arranged along the first circle cc1 and the plurality of columnar dielectric bodies 42 arranged along the second circle cc2 may be adjusted. Thus, the energy of microwaves supplied to each of the columnar dielectric bodies 42 may be adjusted. Accordingly, in a plasma processing apparatus provided with the microwave supply unit 30D, the controllability of plasma density distributions may be further improved.

### Fifth Exemplary Embodiment

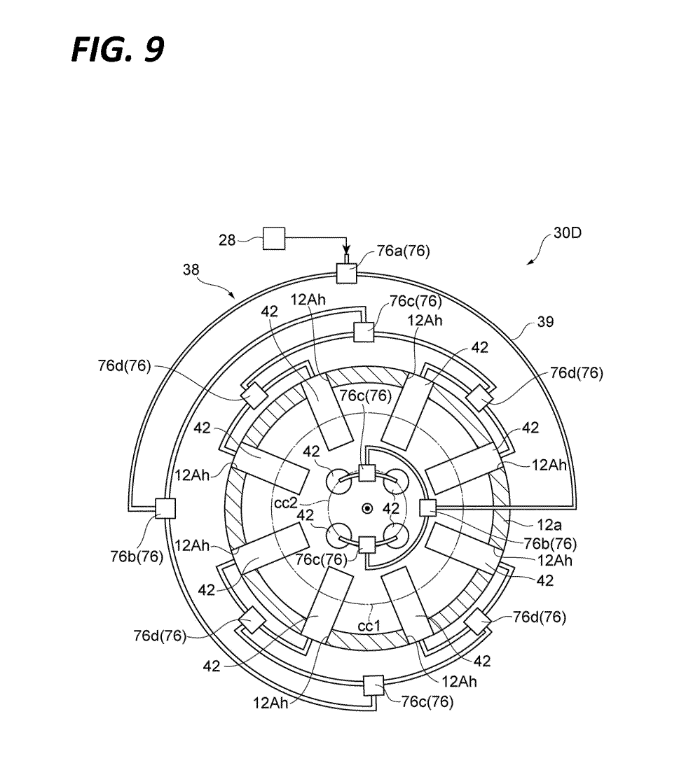

FIG. 9 is a plan view schematically illustrating a microwave supply unit 30E according to a fifth exemplary embodiment. The present exemplary embodiment relates to the microwave supply unit 30E that replaces the microwave supply unit 30B of the plasma processing apparatus 10B. As illustrated in FIG. 9, a plurality of openings 12Bh are formed through the top wall 12c in the direction of the Z-axis.

Some of the plurality of openings 12Bh (in FIG. 9, eight (8) openings 12Bh positioned outside) are arranged along a first circle cc1 centering around the Z-axis. In addition, the others of the plurality of openings 12Bh (in FIG. 9, four (4) openings 12Bh positioned inside) are arranged along a second circle cc2 centering around the Z-axis and having a diameter smaller than that of the first circle cc1.

In addition, a plurality of columnar dielectric bodies 42 extend to the processing space S through the plurality of openings 12Bh. That is, the microwave supply unit 30E is provided with twelve (12) columnar dielectric bodies 42. The positions of the top ends of the columnar dielectric bodies 42, i.e. the base end portions 42a coincide with the height of the top surface of the top wall 12c. In addition, the columnar dielectric bodies 42 extend in the direction of the Z-axis downward below the bottom surface of the top wall 12c. The base end portions 42a of the plurality of columnar dielectric bodies 42 are connected with the other end of the waveguide unit 38 and supplied with microwaves from the microwave generator 28.

Some of the plurality of columnar dielectric bodies 42 (in FIG. 9, eight (8) columnar dielectric bodies 42 positioned) are arranged at predetermined intervals along a first circle cc1 centering around the Z-axis. The others of the plurality of columnar dielectric bodies 42 (in FIG. 9, four (4) columnar dielectric bodies 42 positioned inside) are arranged at predetermined intervals along a second circle cc2 centering around the Z-axis and having a diameter smaller than that of the first circle cc1.

In addition, the microwave supply unit 30E is provided with eleven (11) branching adjustment mechanisms 76. In FIG. 9, a branching adjustment mechanism 76 that branches microwaves input from the microwave generator 28 is referred to as a “first branching adjustment mechanism 76a”. In addition, a branching adjustment mechanism 76 that branches the microwaves branched by the first branching adjustment mechanism 76a is referred to as a “second branching adjustment mechanism 76b” and a branching adjustment mechanism 76 that branches the microwaves branched by the second branching adjustment mechanism 76b is referred to as a “third branching adjustment mechanism 76c”. In addition, a branching adjustment mechanism 76 that branches the microwaves branched by the third branching adjustment mechanism 76c is referred to as a “fourth branching adjustment mechanism 76d”. The microwave supply unit 30E is provided with one (1) first branching adjustment mechanism 76a, two (2) second branching adjustment mechanisms 76b, four (4) third branching adjustment mechanisms 76c, and four (4) fourth branching adjustment mechanisms 76d. According to the microwave supply unit 30E as described above, the microwaves divided into sixteen (16) portions by the first branching adjustment mechanisms 76a, the second branching adjustment mechanisms 76b, the third branching adjustment mechanisms 76Cc, and the fourth branching adjustment mechanisms 76d are supplied to the columnar dielectric bodies 42 arranged along the first circle cc1. In addition, the microwaves divided into eight (8) portions by the first branching adjustment mechanism 76a, the second branching adjustment mechanisms 76b, and the third branching adjustment mechanisms 76c are supplied to the plurality of columnar dielectric bodies 42 arranged along the second circle cc2.

According to the microwave supply unit 30E, since the plurality of columnar dielectric bodies 42 are arranged along the second circle cc2 of which the diameter is smaller than that of the first circle cc1, it is possible to increase the plasma density in the vicinity of Z-axis.

In addition, when the branching ratio of microwaves input from the microwave generator 28 is adjusted using the first branching adjustment mechanism 76a, the energy of microwaves supplied to the plurality of columnar dielectric bodies 42 arranged along the first circle cc1 and the plurality of columnar dielectric body 42 arranged along the second circle cc2 may be adjusted. Thus, the energy of microwaves supplied to each of the plurality of columnar dielectric bodies 42 may be adjusted. Accordingly, in a plasma processing apparatus provided with the microwave supply unit 30D, the controllability of plasma density distributions may be further improved.

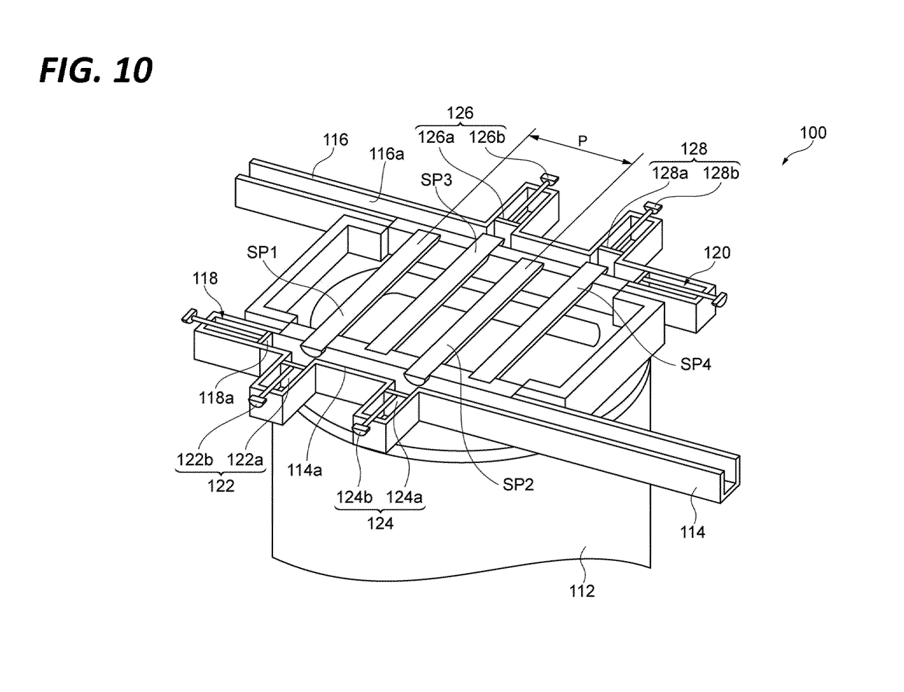

Hereinafter, descriptions will be made on Test Example 1 which was performed to evaluate the above-described exemplary embodiments. FIG. 10 is a perspective view illustrating a configuration of a plasma processing apparatus used for Test Example 1.

The plasma processing apparatus 100 illustrated in FIG. 10 includes four (4) dielectric rods SP1 to SP4 on the top of the processing container 112. The rods SP1 to SP4 have a diameter of 40 mm and a length of 353 mm and are arranged parallel to each other at regular intervals. In addition, as illustrated in FIG. 10, the rods are arranged in one direction in the order of the rod SP1, the rod SP3, the rod SP2, and the rod SP4. The distance P between the rod SP1 and the rod SP2 was set to 300 mm.

In addition, the plasma processing apparatus 100 is provided with two rectangular waveguides 114, 116. The cross-sectional size of each of the rectangular waveguides 114, 116 was 109.2 mm×54.6 mm which conforms to the EIA Standard WR-430. The waveguides 114, 116 extend in a direction orthogonal to the extension direction of the rods SP1 to SP4 and the rods SP1 to SP4 are installed to be interposed therebetween. The waveguide 114 has a plunger 118 at the reflection end thereof, and the waveguide 116 has a plunger 120 at the reflection end thereof. One end of each of the rods SP1, SP2 is positioned within the waveguide path of the waveguide 114 and the other end of each of the rods SP1, SP2 is terminated just in front of the waveguide path of waveguide 116. Specifically, the one end of each of the rods SP1, SP2 enters into the waveguide 114 by a length of 30 mm. In addition, one end of each of the rods SP3, SP4 is positioned within the waveguide path of the waveguide 116, and the other end of each of the rods SP3, SP4 is terminated just in front of the waveguide path of the waveguide 114. Specifically, the one end of each of the rods SP3, SP4 enters into the waveguide 116 by a length of 30 mm.

Plungers 122, 124 are attached to the waveguide 114. The plunger 122 includes a reflector 122a and a position adjustment mechanism 122b. The reflector 122a is opposed to the one end of the rod SP1 through the waveguide path of the waveguide 114. The position adjustment mechanism 122b functions to adjust the position of the reflector 122a from one surface of the waveguide 114 (indicated by reference numeral 114a) that defines the waveguide path. In addition, the plunger 124 includes a reflector 124a and a position adjustment mechanism 124b. The reflector 124a is opposed to the one end of the rod SP2 through the waveguide path of the waveguide 114. The position adjustment mechanism 124b may adjust the position of the reflector 124a from the one surface 114a of the waveguide 114.

In addition, plungers 126, 128 are attached to the waveguide 116. The plunger 126 includes a reflector 126a and a position adjustment mechanism 126b. The reflector 126a is opposed to the one end of the rod SP3 through the waveguide path of the waveguide 116. The position adjustment mechanism 126b may adjust the position of the reflector 126a from one surface of the waveguide 116 (indicated by reference numeral 116a) that defines the waveguide path of the waveguide 116. In addition, the plunger 128 includes a reflector 128a and a position adjustment mechanism 128b. The reflector 128a is opposed to the one end of the rod SP4 through the waveguide path of the waveguide 116. The position adjustment mechanism 128b may adjusts the position of the reflector 128a of the one surface 116a of the waveguide 116 that defines the waveguide path.

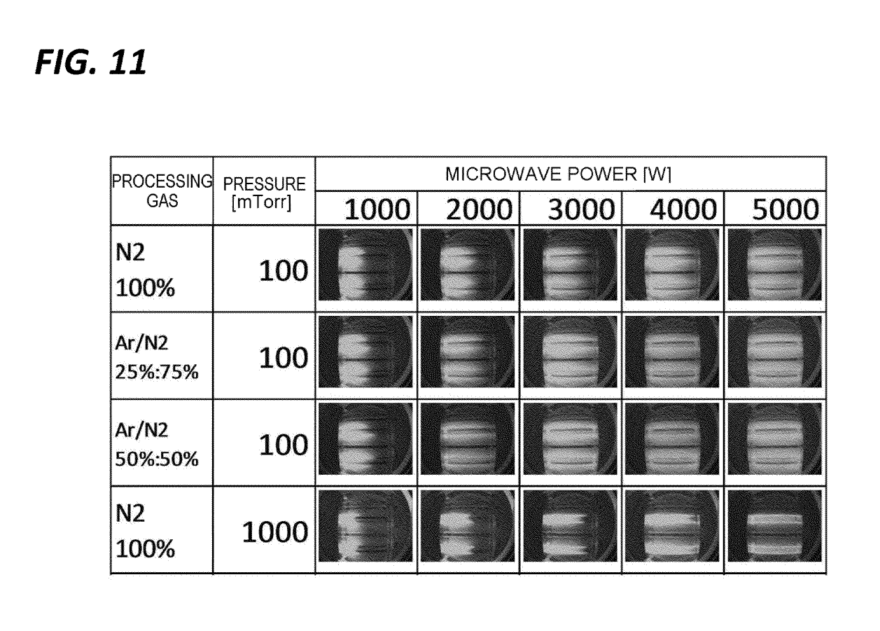

In Test Example 1, a processing gas was supplied to the inside of the processing container 112 of the plasma processing apparatus 100 configured as described above, and microwaves having frequency of 2.45 GHz were supplied to the waveguide 114. In addition, in Test Example 1, the processing gas, the microwave power supplied to the waveguide 114, and the pressure of the processing container 112 were changed as parameters as illustrated in FIG. 11.

In addition, in Test Example 1, plasma emission states were photographed from a position below the rods SP1, SP2. FIG. 11 represents images of plasma emission states of Test Example 1. In the images represented in FIG. 11, portions with relatively high luminance show plasma emission in the vicinity of the rods SP1, SP2. Accordingly, as a result of Test Example 1, it was confirmed that the plasma generation positions may be controlled in the vicinity of the rods SP1, SP2. From this, it was confirmed that the plasma generation positions may be concentrated in the vicinity of the rods, i.e. the columnar dielectric bodies.

Further, as a result of Test Example 1, it was observed that plasma was generated to extend from the vicinity of the microwave incident ends of the rods SP1, SP2 toward the other end sides. Specifically, it was confirmed that the length of plasma extending along the rods SP1, SP2 is increased as the microwave power supplied to the rods SP1, SP2 is increased. For example, when the processing gas was N₂ only, the pressure was 100 mTorr, and the microwave power was 5000 W, plasma was generated along the entire area of the rods SP1, SP2. Further, the plasma was striped. It is supposed that this results from occurrence of standing waves within the rods SP1, SP2. Unlike this, when the processing gas and the pressure were set to the same conditions and the microwave power was set to 2000 W, plasma was generated only at the regions from the incident ends of the rods SP1, SP2 to the middle portions thereof and striped plasma that indicates occurrence of standing waves was not observed. From this, it was confirmed that even when microwaves of a considerably high power are generated by the microwave generator, occurrence of standing waves may be prevented when the microwaves are branched and supplied to a plurality of columnar dielectric bodies.

In the foregoing, various exemplary embodiments have been described. However, various modified aspects may be made without being limited to the exemplary embodiments. For example, although a plurality of columnar dielectric bodies are arranged along two concentric circles, i.e. the first circle cc1 and the second circle cc2 in the fourth exemplary embodiment and the fifth exemplary embodiment, the columnar dielectric bodies may be provided along three or more concentric circles. Further, the shape of the columnar dielectric bodies is not limited to the cylindrical columnar shape and may be an elliptical cross-section shape or any of other shapes such as a square column shape.

In addition, although a rectangular waveguide is used as the waveguide in the above-described exemplary embodiments, a coaxial waveguide may be used as the waveguide.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A plasma processing apparatus comprising:
a processing container having a cylindrical columnar shape centering around a predetermined axis and defining a processing space therein;
a plurality of columnar dielectric bodies installed at a top side of the processing space;
a microwave generator configured to generate microwaves;
a waveguide unit configured to connect the microwave generator and the plurality of columnar dielectric bodies; and
a stage installed within the processing container to intersect with the predetermined axis,
wherein the plurality of columnar dielectric bodies are arranged at predetermined intervals along a circumferential direction around the predetermined axis within the processing space, and
the waveguide unit branches microwaves input from the microwave generator and supplies the branched microwaves to the plurality of columnar dielectric bodies.

2. The plasma processing apparatus of claim 1, wherein the processing container includes a side wall configured to determine the processing space from a lateral side, the side wall being formed with a plurality of openings along the circumferential direction around the predetermined axis, and
the plurality of columnar dielectric bodies extend to the inside of the processing container through the plurality of openings.

3. The plasma processing apparatus of claim 1, wherein the processing container includes a top wall that defines the processing space from the top side, the top wall being formed with a plurality of openings in the circumferential direction around the predetermined axis, and
the plurality of columnar dielectric bodies extend in a direction parallel to the predetermined axis through the plurality of openings.

4. The plasma processing apparatus of claim 1, wherein the waveguide unit includes a branching adjustment mechanism configured to adjust a branching ratio of the microwaves.

5. The plasma processing apparatus of claim 1, wherein the columnar dielectric bodies are made of quartz and each of the columnar dielectric bodies is formed in a cylindrical columnar shape having a diameter of 35 mm to 45 mm.

6. The plasma processing apparatus of claim 1, wherein the columnar dielectric bodies are made of alumina and each of the columnar dielectric bodies is formed in a cylindrical columnar shape having a diameter of 23 mm to 30 mm.
